(19) United States
(12) Patent Application Publication
(10) Pub. No.: US 2006/0076604 A1
(43) Pub. Date: Apr. 13, 2006

(54) Virtual ground memory array and method therefor

(76) Inventor: Erwin J. Prinz, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/961,296

(22) Filed: Oct. 8, 2004

(51) Int. Cl. H01L 29/78; H01L 21/336

(52) U.S. Cl. 257/311; 257/314; 438/301; 438/257

(57) ABSTRACT

A virtual ground memory array (VGA) is formed by forming source/drain lines using a patterned photoresist layer over a sacrificial layer. The sacrificial layer is opened according to the pattern of the patterned photoresist layer. The openings are implanted to form the source/drain lines then filled with a conformal layer of dielectric material that can be etched selective to the sacrificial layer. A chemical mechanical polishing (CMP) step is then performed until the top of the sacrificial layer is exposed. Without requiring a mask, the sacrificial layer is etched away while leaving the dielectric material over the source/drain lines. The removal of the sacrificial layer exposes the substrate between the source/drain lines. A gate dielectric and storage layer is formed between the source drain lines and over the dielectric material. The word line is then formed over the gate dielectric and storage layer.

### RELATED APPLICATIONS

This application is related to U.S. Patent Application docket number SC13572TP, titled “A Virtual Ground Memory Array and Method Therefor” filed concurrently herewith and assigned to the assignee hereof.

This application is related to U.S. Patent Application docket number SC13597TP titled, “Method For Forming a Multi-Bit Non-Volatile Memory Device” filed concurrently herewith and assigned to the assignee hereof.

### FIELD OF THE INVENTION

The present invention relates to virtual ground memory arrays (VGAs), and more particularly, to VGAs with enhanced separation between source/drain and word line.

### RELATED ART

Virtual ground memory arrays (VGAs) are particularly useful because they are very high density. Their preferred usage is in non-volatile memories. VGAs do not require field isolation but require control of both the source and drain of the memory transistors that serve as memory elements. The VGA type memory is widely applicable to the various types of non-volatile memories, such as ROMs, PROMs, OTPROMs, flash, EPROMs, and EEPROMs. The VGA is also applicable to different storage mediums such as floating gate and nitride. One of the characteristics of some VGAs is that the word line, which functions as the gate of the transistors for a given row of memory transistors, passes over the sources and drains. Although this is useful in achieving the high density of memory elements of VGAs, this also increases the capacitance between the word line (gate) and the drain. This is also sometimes called the Miller capacitance. The gate/drain capacitance, however, is preferably low.

One of the techniques in the past to reduce the gate/drain capacitance has been to grow an oxide layer over the sources and drains to provide increased separation between the gate and drain, thereby reducing gate/drain capacitance. While this is an effective approach for reducing the capacitance, it also introduces additional difficulties. The oxide growth has the effect of lowering the source/drains below the top surface of the silicon because the oxidation process involves using the substrate silicon in forming the oxide. This in turn causes what is known as a bird's beak similar to that found in LOCOS type isolation. The bird's beak has the effect of increasing the gate dielectric thickness at the edge of the gate where the sources and drains are. This is difficult to control and alters the operation of the memory transistor. Also this bird's beak has not changed much as the processing and lithography technology has improved to make transistors smaller. Thus the deleterious effect of the bird's beak actually gets more significant as the technology has improved and the transistors get smaller.

Thus, there is a need for a method and structure that reduces alleviates these problems while reducing the gate to drain capacitance of memory transistors in a VGA.

### BRIEF DESCRIPTION OF THE DRAWINGS

The present invention is illustrated by way of example and not limited by the accompanying figures, in which like references indicate similar elements, and in which:

FIG. 1 is a cross section of a VGA according to an embodiment of the invention at a stage in processing;

FIG. 2 is a cross section of the VGA of FIG. 1 at a subsequent stage in processing;

FIG. 3 is a cross section of the VGA of FIG. 2 at a subsequent stage in processing;

FIG. 4 is a cross section of the VGA of FIG. 3 at a subsequent stage in processing;

FIG. 5 is a cross section of the VGA of FIG. 4 at a subsequent stage in processing;

FIG. 6 is a cross section of the VGA of FIG. 5 at a subsequent stage in processing; and

FIG. 7 is a cross section of the VGA of FIG. 6 at a subsequent stage in processing.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

In one aspect, a virtual ground memory array (VGA) is formed by forming source/drain lines using a patterned photoresist layer over a sacrificial layer. The sacrificial layer is opened according to the pattern of the patterned photoresist layer. The openings are implanted to form the source/drain lines, then filled with a conformal layer of dielectric material that can be etched selective to the sacrificial layer. A chemical mechanical polishing (CMP) step is then performed until the top of the sacrificial layer is exposed. Without requiring a mask, the sacrificial layer is etched away while leaving the dielectric material over the source/drain lines. The removal of the sacrificial layer exposes the substrate between the source/drain lines. A gate dielectric and storage layer is formed between the source drain lines and over the dielectric material. The word line is then formed over the gate dielectric and storage layer. This is better understood with reference to the drawings and the following description.

Shown in FIG. 1 is a semiconductor device that is a portion of a virtual ground memory array (VGA) 10 comprising a substrate 12, a buffer layer 14 over substrate 12, and a sacrificial layer 16 over buffer layer 14. Substrate 12 is preferably a bulk silicon substrate but could be an SOI substrate also and could be a different semiconductor material than silicon. The portion of substrate 12 shown in FIG. 1 is doped as a well; preferably a P well. Buffer layer 14 is preferably a grown oxide of between 50 and 100 Angstroms. Sacrificial layer 16 is preferably nitride but could be a different material and is between 1000 and 2000 Angstroms in thickness.

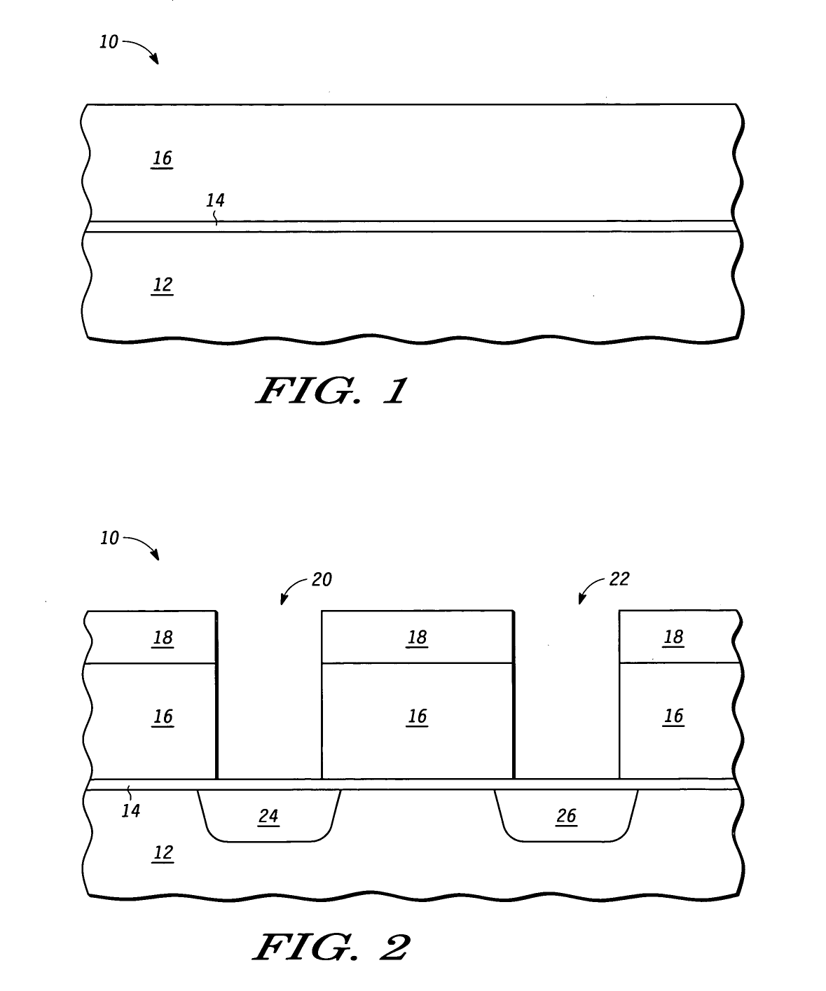

Shown in FIG. 2 is VGA 10 after depositing a photoresist layer 18, patterning photoresist layer 18, etching sacrificial layer 16 to form openings 20 and 22 in sacrificial layer 16, and implanting source/drain region 24 in substrate 12 through opening 20 and source/drain region 26 in substrate 12 through opening 22. Source/drain regions 24 and 26 are preferably doped to N type to form N channel transistors. N channel transistors are preferred over P channel transistors because of their higher mobility. Alternatively, substrate 12 could be doped to form an N well and P channel transistors could be formed by doping source/drain regions 24 and 26 to P type. The implant dopant is preferably arsenic to limit the lateral diffusion but could be phosphorus. Source/drain regions 24 and 26 function as bit line regions for VGA 10. Source/drain regions can be considered current terminals of a transistor.

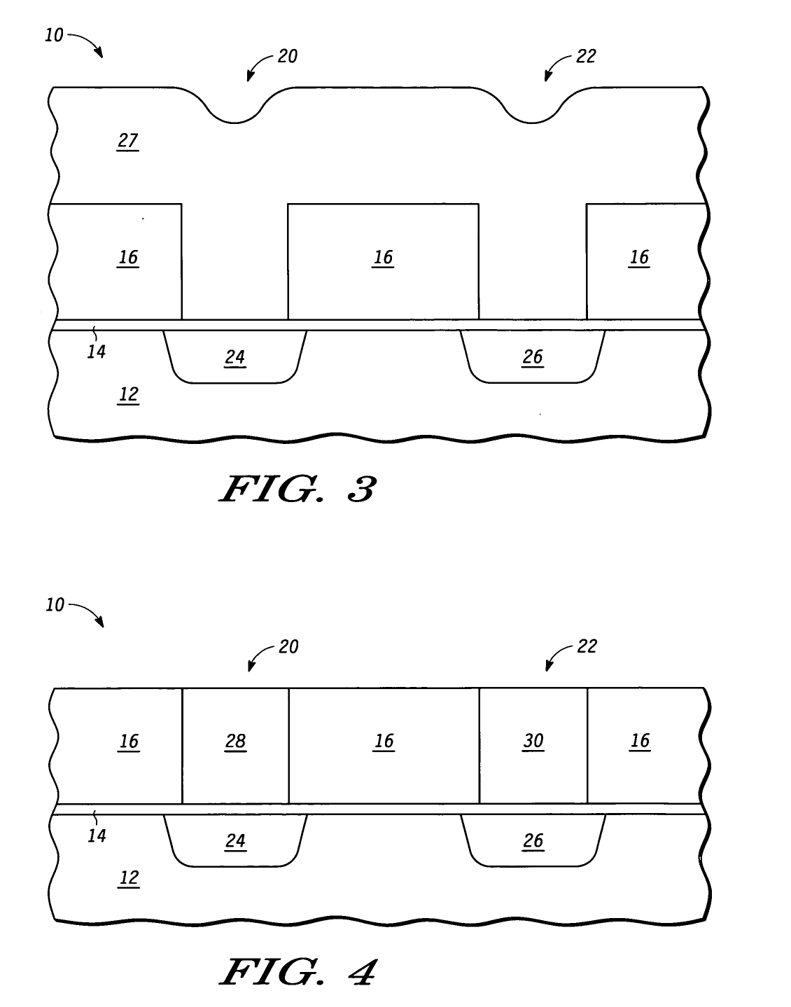

Shown in FIG. 3 is VGA 10 after deposition of a somewhat conformal dielectric layer 24 that is sufficiently thick, preferably 1000 to 2000 Angstroms, that it fills openings 20 and 22. Dielectric layer 27 is preferably oxide, and more particularly oxide from tetraethylorthosilicate (TEOS), but could be a different material. Dielectric layer 27 preferably has a low dielectric constant and has a different etch characteristic than that of sacrificial layer 16 so that sacrificial layer 16 can be etched selective to dielectric layer 27. Thus, there would be benefit to having a lower k material than oxide if other processing restraints can be met and if it can be selectively etched to sacrificial layer 16. Sacrificial layer 16 can also be different than nitride in order to meet the requirements on dielectric layer 27.

Shown in FIG. 4 is VGA 10 after a chemical mechanical polishing (CMP) step that is performed until sacrificial layer 16 is exposed. The result is a relatively flat surface in which dielectric layer 27 has been polished back to leave dielectric region 28 in opening 20 and dielectric region 30 in opening 22. The CMP step will reduce the thickness of sacrificial layer 16 somewhat to ensure that sacrificial layer 16 is exposed in all locations of VGA 10. Sacrificial layer 16 can be viewed as a polish stop because when the amount of oxide being removed becomes constant, then it is known that no more polishing is necessary.

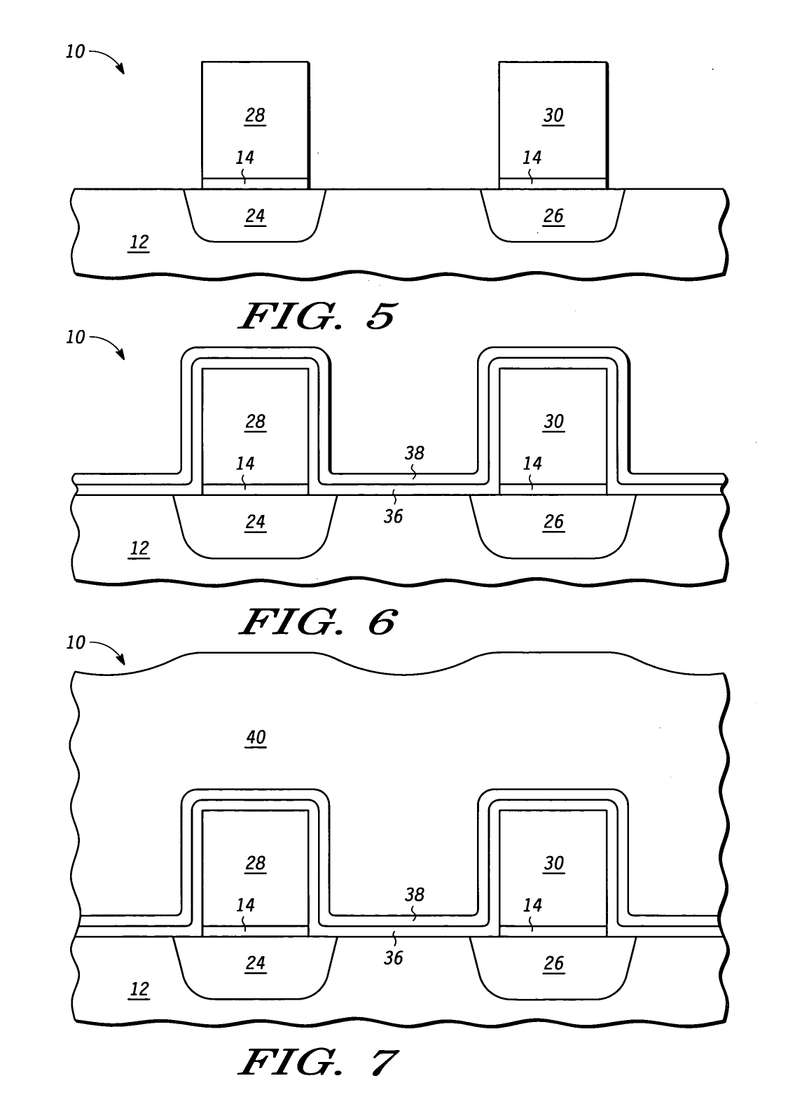

Shown in FIG. 5 is VGA 10 after etching sacrificial layer 16 using an etchant, preferably hot phosphoric acid, that etches nitride selective to oxide. Other etchants may be used instead that achieve this objective. Also removed is buffer layer 14 in the area that was under sacrificial layer 28. The etchant that is used in this removal of buffer layer 14 also etches dielectric regions 28 and 30 but not significantly so. Buffer layer 14 remains under dielectric regions 28 and 30.

Shown in FIG. 6 is VGA 10 after forming a gate dielectric layer 36 and a storage layer 38 on gate dielectric 36. Gate dielectric 36 is preferably oxide grown at relatively high temperature, about 1000 degrees Celsius, to be of high quality. Gate dielectric 36 is thus thicker adjacent to substrate 12 than on dielectric regions 30 and 28. Gate dielectric 36 is preferably 50 to 100 Angstroms. Storage layer 38 is preferably a layer of nanocrystals surrounded by dielectric and another layer of oxide over the nanocrystals. Storage layer 38 could also be a nitride layer with an oxide layer over the nitride layer. Storage layer 38 could also be a floating gate with an oxide layer over it, but another masking step would likely be required to ensure that that the floating gate for each memory transistor would be isolated from the others. The heat during the formation of gate dielectric 36 causes source/drain regions 24 and 26 to further diffuse outward and down.

Shown in FIG. 7 is VGA 10 after formation of a word line 40. Word line 40 is preferably polysilicon but another suitable gate material could be used. Word line 40 functions as a gate for a memory transistor that has source/drains regions 24 and 26 as its source and drain. Word line 40 runs perpendicular to source/drain regions 24 and 26 in their function as bit lines. Word line 40 has a uniform height above substrate 12 in the area, the channel of the memory transistor, between source/drain regions 24 and 26 and word line 40 is spaced from source/drain regions 24 and 26 by dielectric regions 28 and 30, respectively. Thus, there is an effective reduction in the gate to drain capacitance of the memory transistors due to the dielectric spacers, which are effectively dielectric regions 28 and 30 and buffer layer 14. The dielectric spacers are substantially rectangular in cross section and they have substantially planar sidewalls and bottom surfaces. This can also be viewed as the dielectric spacers having a bottom surface that is substantially coplanar with the top surface of substrate 12 in the channel region. This method and structure should also be able to be used with similar effect as lithography and processing improvements reduce the geometries, such as channel lengths. Further, this is achieved while not requiring any extra masks than normally required for a VGA.

As an alternative to using just dielectric material to fill openings 20 and 22, a conductive material could be applied directly to the exposed portions of source/drain regions prior to applying dielectric layer 24. In such case the conductive material could be doped polysilicon. It may be desirable to put a sidewall spacer in openings 20 and 22 prior to forming the conductive material. Using conductive material on the bit line regions would beneficially increase the bit line conductivity but may detrimentally increase the gate to drain capacitance. The thickness of the conductive material would be relevant to that tradeoff.

In the foregoing specification, the invention has been described with reference to specific embodiments. However, one of ordinary skill in the art appreciates that various modifications and changes can be made without departing from the scope of the present invention as set forth in the claims below. For example, CMP was designated as the way to achieve a planar surface and expose sacrificial layer 16 but another process may be able to achieve the desired intermediate result shown in FIG. 4. Similarly, the gate dielectric was described as grown oxide but could instead be a deposited high k dielectric. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method of making a semiconductor device, the method comprising:
forming a first layer over a semiconductor material;
forming an opening in the first layer;
introducing dopants into the semiconductor material through the opening;
forming a dielectric structure, wherein the forming the dielectric structure includes forming dielectric material in the opening;
forming a layer of charge storing material over the dielectric structure.

2. The method of claim 1 further comprising:
removing the first layer after the forming the dielectric material and prior to forming the layer of charge storing material.

3. The method of claim 2 wherein the removing further includes selectively etching the first layer with respect to the dielectric material.

4. The method of claim 1 wherein:
the forming dielectric material in the opening includes forming a layer of dielectric material over the first layer;
the forming the dielectric structure further includes planarizing the dielectric material, wherein the planarizing leaves dielectric material in the opening.

5. The method of claim 4 wherein first layer is used as a polish stop during the planarizing.

6. The method of claim 1 further comprising:
forming a current electrode region in the semiconductor material wherein the forming the current electrode region includes the introducing dopants into the semiconductor material through the opening.

7. The method of claim 6 wherein the current electrode region is a current electrode region for a virtual ground array.

8. The method of claim 1 further comprising:
forming a bit line in the semiconductor material wherein the forming the bit line includes the introducing dopants into the semiconductor material through the opening.

9. The method of claim 1 wherein the layer of charge storing material include nanoclusters of charge storing material.

10. The method of claim 1 wherein the layer of charge storing material includes nitride.

11. The method of claim 1 further comprising:
forming a line of conductive material over the dielectric structure and over the charge storing layer.

12. The method of claim 11 wherein the line conductive material is characterized as a word line.

13. The method of claim 11 wherein the forming the line of conductive material further includes:
forming a layer of conductive material over the layer of charge storing material and dielectric structure;
patterning the layer of conductive material.

14. The method of claim 11 wherein the dielectric structure is characterized as a line running in a first direction, wherein the line of conductive material runs in a second direction generally perpendicular to the first direction.

15. The method of claim 1 further comprising:
forming a dielectric layer over the semiconductor material prior to forming the first layer;
wherein the forming the opening in the first layer includes etching the first layer and using the dielectric layer as an etch stop;
wherein forming dielectric material in the opening includes forming dielectric material in the opening over the dielectric layer.

16. The method of claim 1 wherein the dielectric material includes tetra ethyl ortho silicate (TEOS).

17. The method of claim 1 wherein the introducing the dopant includes implanting the dopant through the opening.

18. The method of claim 1 further comprising:
forming a dielectric layer over the dielectric structure, wherein the layer of charge storing material is formed over the dielectric layer.

19. A method of making a semiconductor device, the method comprising:
forming a first layer over a semiconductor material;
forming openings in the first layer;
introducing dopants into the semiconductor material through the opening;
forming a dielectric structure, wherein the forming the dielectric structure includes:
depositing a layer of dielectric material over the first layer after forming the openings;
planarizing the dielectric material, wherein the planarizing leaves dielectric material in the opening;
removing the first layer after the planarizing;
forming a conductive line over the dielectric structure.

20. The method of claim 19 wherein the first layer is used as a polish stop during the planarizing.

21. The method of claim 19 further comprising:
forming a layer of charge storing material over the semiconductor material.

22. The method of claim 19 wherein the dielectric structure is characterized as a line running in a first direction, wherein the conductive line runs in a second direction generally perpendicular to the first direction.

23. The method of claim 19 further comprising:
forming a current electrode region in the semiconductor material, wherein the forming the current electrode region includes the introducing dopants into the semiconductor material through the opening.

24. The method of claim 23 wherein:
the conductive line is characterized as a word line;
the current terminal region and conductive line are implemented in a virtual ground array.

25. The method of claim 19 wherein the conductive line is characterized as a word line.

26. A method of making a memory device, the method comprising:
forming a first layer over semiconductor material;
forming openings in the first layer;
forming current electrode regions in the semiconductor material, wherein the forming current electrode regions includes introducing dopants into the semiconductor material through the openings;
forming dielectric structures, wherein the forming dielectric structures includes forming dielectric material in the openings;
forming a layer of charge storing material over the dielectric structures;
forming word lines over the layer of charge storing material and over the dielectric structures.

27. The method of claim 26 wherein:
each of the dielectric structures is characterized as a line running in a first direction;
each of the word lines runs in a second direction generally perpendicular to the first direction.

28. The method of claim 26 wherein the current electrode regions are characterized as bit lines.

29. The method of claim 26 wherein the current electrode regions and word lines are implemented in a virtual ground array.

30. The method of claim 26 wherein:
the forming dielectric material in the openings includes forming a layer of dielectric material over the first layer;
the forming the dielectric structures further includes planarizing the dielectric material, wherein the planarizing leaves dielectric material in the openings and removes dielectric material outside of the openings.

31. The method of claim 26 wherein first layer is used as a polish stop during the planarizing.

32. The method of claim 26 further comprising:
removing the first layer before forming the layer of charge storing material.

33. A memory device comprising:
a current terminal region in a semiconductor material;
a dielectric structure over the current terminal region, the dielectric structure having opposing side walls;
a charge storing structure over the dielectric structure;
a word line over the charge storing structure and over the dielectric structure.

34. The memory device of claim 33 wherein the current terminal region is characterized as a bit line region.

35. The memory device of claim 33 wherein the dielectric structure is characterized as a line.

36. The memory device of claim 35 wherein the line runs in a first direction and the word line runs in a second direction generally perpendicular to the first direction.

37. The memory device of claim 33 wherein the word line and current terminal region is implement in a virtual ground array.

38. A memory device comprising:
a current terminal region in semiconductor material, the semiconductor material having a generally planar top surface;
a dielectric line located over the current terminal region, the dielectric line has sidewalls and a bottom surface that is generally planar and is generally parallel to the top surface of the semiconductor material;
a word line over the dielectric line.

39. The memory device of claim 38 wherein the dielectric line runs in a first direction and the word line runs in a second direction generally perpendicular to the first direction.

40. The memory device of claim 38 wherein the current terminal region is characterized as running in a first direction and the dielectric line runs generally in the first direction.

41. The memory device of claim 38 wherein the current terminal region and word line are implemented in a virtual ground array.
